(19) United States
(12) Patent Application Publication
(10) Pub. No.: US 2016/0358883 A1
(43) Pub. Date: Dec. 8, 2016

(54) BUMP FORMING METHOD, BUMP FORMING APPARATUS, AND SEMICONDUCTOR DEVICE MANUFACTURING METHOD

(71) Applicant: SHINKAWA LTD., Tokyo (JP)

(72) Inventors: HIROAKI YOSHINO, Tokyo (JP); TOSHIHIKO TOYAMA, Tokyo (JP)

(73) Assignee: SHINKAWA LTD., Tokyo (JP)

(21) Appl. No.: 15/241,086

(22) Filed: Aug. 19, 2016

Related U.S. Application Data
(63) Continuation of application No. PCT/JP2014/061608, filed on Apr. 24, 2014.

(30) Foreign Application Priority Data
Feb. 20, 2014 (JP) 2014-030413

(51) Int. Cl. H01L 23/00; B23K 20/00; B23K 20/26; H01L 25/10

(52) U.S. Cl. CPC H01L 24/81; H01L 24/75; H01L 24/78; H01L 24/85; H01L 24/17; H01L 24/14; H01L 25/10; B23K 20/004; B23K 20/26; H01L 2224/48091; H01L 2224/0401

(57) ABSTRACT

A bump forming method includes: a bonding step of bonding the leading end of a wire extending out of the tip of a bonding tool to a first point (X1); a wire pay-out step of moving the bonding tool in a direction away from the first point; a thin portion forming step of pressing a portion of the wire at a second point (X2) on a reference plane using the bonding tool to form a thin portion (64) in the wire; a wire shaping step of shaping the wire bonded to the first point in a manner rising from the reference plane; and a bump forming step of cutting the wire at the thin portion to form a bump (60) having a shape rising from the reference plane at the first point. It is therefore possible to form a bump having a desired height more easily and efficiently.

### CROSS REFERENCE TO RELATED APPLICATIONS

This application is a Continuation of PCT International Application No. PCT/JP2014/061608, filed on Apr. 24, 2014, which claims priority under 35 U.S.C §119(a) to Patent Application No. 2014-030413, filed in Japan on Feb. 20, 2014, all of that are hereby expressly incorporated by reference into the present application.

### TECHNICAL FIELD

The present invention relates to a bump forming method, a bump forming apparatus, and a semiconductor device manufacturing method.

### BACKGROUND ART

As a bump forming method of semiconductor devices, there is known a bump forming method to which a wire bonding method is applied. For example, a method has been known in which a pressure-bonding ball formed at the leading end of a wire is bonded onto an electrode on a semiconductor die and, on this pressure-bonding ball, a neck portion of the wire having a certain height is formed to form a bump (see Patent Document 1). Such a bump may be called a stud bump (registered trademark).

### CITATION LIST

### Patent Document

Patent Document 1: Japanese Patent No. 4509043

### SUMMARY OF THE INVENTION

### Technical Problem

However, in the invention described in Patent Document 1, when the bump gets above a certain height, it may be difficult for the neck portion of the wire to stand upright and it may also be difficult to cut the wire by operating the bonding tool. As another related art, there has also been known a method of forming a stacked bump by stacking multiple bumps, but the method suffers from a problem in that even stacking bumps is cumbersome and time-consuming or bumps may be misaligned and a desired bump strength may not be provided.

Incidentally, three dimensional packaging configurations such as TSV (Through Silicon Via) and POP (Package On Package) are currently becoming mainstream. In such packaging configurations, it is required to form bumps having above a certain height at a pitch distance narrowed to some extent and there is an increasing need to form such bumps more easily and efficiently.

It is hence that the present invention provides a bump forming method, a bump forming apparatus, and a semiconductor device manufacturing method with which the above described problem can be solved.

### Solution to Problem

An aspect of the present invention is directed to a bump forming method of semiconductor devices using a bonding tool with a wire inserted therethrough, the method including: a bonding step of lowering the bonding tool toward a first point on a reference plane and bonding the leading end of the wire extending out of the tip of the bonding tool to the first point; a wire pay-out step of moving the bonding tool in a direction away from the first point while paying out the wire from the tip of the bonding tool; a thin portion forming step of pressing a portion of the wire at a second point on the reference plane using the bonding tool to form a thin portion in the wire; a wire shaping step of moving the bonding tool along with the thin portion of the wire and shaping the wire bonded to the first point in a manner rising from the reference plane; and a bump forming step of cutting the wire at the thin portion to form a bump having a shape rising from the reference plane at the first point.

In accordance with the arrangement above, the wire is formed with a thin portion using the bonding tool and the wire bonded to the first point is shaped in a manner rising from the reference plane, and then the wire is cut at the thin portion, so that a bump is formed having a shape rising from the reference plane at the first point. It is therefore possible to form a bump having a desired height more easily and efficiently.

In the bump forming method, in the wire pay-out step, the bonding tool is moved to a predetermined height in a direction perpendicular to the reference plane, moved toward the second point in the parallel direction while being kept at the predetermined height, and moved toward the second point in the direction perpendicular to the reference plane.

In the bump forming method, in the wire pay-out step, the bonding tool is moved to a predetermined height in a direction perpendicular to the reference plane and moved toward the second point in a predetermined curve.

In the bump forming method, in the wire pay-out step, the bonding tool is moved toward above the second point to a predetermined height in a predetermined curve and moved toward the second point in a direction perpendicular to the reference plane.

In the bump forming method, in the wire shaping step, the bonding tool is moved toward above a third point on the reference plane, the third point configured on the line connecting the second point and the first point with the first point being arranged between the third point and the second point.

In the bump forming method, in the wire shaping step, the bonding tool is moved to a predetermined height in a direction perpendicular to the reference plane and moved toward the third point in the parallel direction while being kept at the predetermined height.

In the bump forming method, in the wire shaping step, the bonding tool is moved toward above the third point to a predetermined height in a predetermined curve.

The bump forming method can further include, after the wire shaping step and before the wire cutting step, a step of raising the bonding tool while paying out the wire from the tip of the bonding tool.

In the bump forming method, in the bump forming step, the bonding tool is raised further, with the wire being restrained by a wire clamper, to cut the wire at the thin portion.

The bump forming method can further include, before the bonding step, a step of forming the leading end of the wire into a ball.

In the bump forming method, in the thin portion forming step, the wire is pressed such that the thin portion of the wire has a thickness approximately half the diameter of the wire.

A semiconductor device manufacturing method according to an aspect of the present invention includes the bump forming method.

An aspect of the present invention is directed to a bump forming apparatus for forming a bump of semiconductor devices using a bonding tool with a wire inserted therethrough, the apparatus including a control unit for controlling the operation of the bonding tool, in which the control unit is configured to perform: a bonding step of lowering the bonding tool toward a first point on a reference plane and bonding the leading end of the wire extending out of the tip of the bonding tool to the first point; a wire pay-out step of moving the bonding tool in a direction away from the first point while paying out the wire from the tip of the bonding tool; a thin portion forming step of pressing a portion of the wire at a second point on the reference plane using the bonding tool to form a thin portion in the wire; a wire shaping step of moving the bonding tool along with the thin portion of the wire and shaping the wire bonded to the first point in a manner rising from the reference plane; and a bump forming step of cutting the wire at the thin portion to form a bump having a shape rising from the reference plane at the first point.

In accordance with the arrangement above, the wire is formed with a thin portion using the bonding tool and the wire bonded to the first point is shaped in a manner rising from the reference plane, and then the wire is cut at the thin portion, so that a bump is formed having a shape rising from the reference plane at the first point. It is therefore possible to form a bump having a desired height more easily and efficiently.

### Advantageous Effects of the Invention

In accordance with the present invention, it is possible to form a bump having a desired height more easily and efficiently.

### BRIEF DESCRIPTION OF THE DRAWINGS

FIG. 1 illustrates a configuration of a bump forming apparatus according to an embodiment.

FIGS. 2 (A) to 2 (E) illustrate a bump forming method according to the embodiment.

FIGS. 3 (A) to 3 (C) illustrate a bump forming method according to the embodiment.

FIG. 4 is a timing diagram illustrating the bump forming method according to the embodiment.

FIGS. 5 (A) and 5 (B) are diagrams (photographs) illustrating multiple bumps formed using the bump forming method according to the embodiment.

FIG. 6 illustrates an example of a semiconductor device including bumps formed using the bump forming method according to the embodiment.

FIG. 7 is a timing diagram illustrating a bump forming method according to a variation of the embodiment.

FIG. 8 is a timing diagram illustrating a bump forming method according to a variation of the embodiment.

FIG. 9 is a timing diagram illustrating a bump forming method according to a variation of the embodiment.

FIG. 10 is a timing diagram illustrating a bump foil ling method according to a variation of the embodiment.

### DESCRIPTION OF EMBODIMENTS

An embodiment of the present invention will hereinafter be described. In the following description of the drawings, identical or similar components are designated by the same or similar reference symbols. The drawings are illustrative only and the dimensions and geometries of various parts are schematic only, and the technical scope of the present invention should not be understood as being limited to the embodiment.

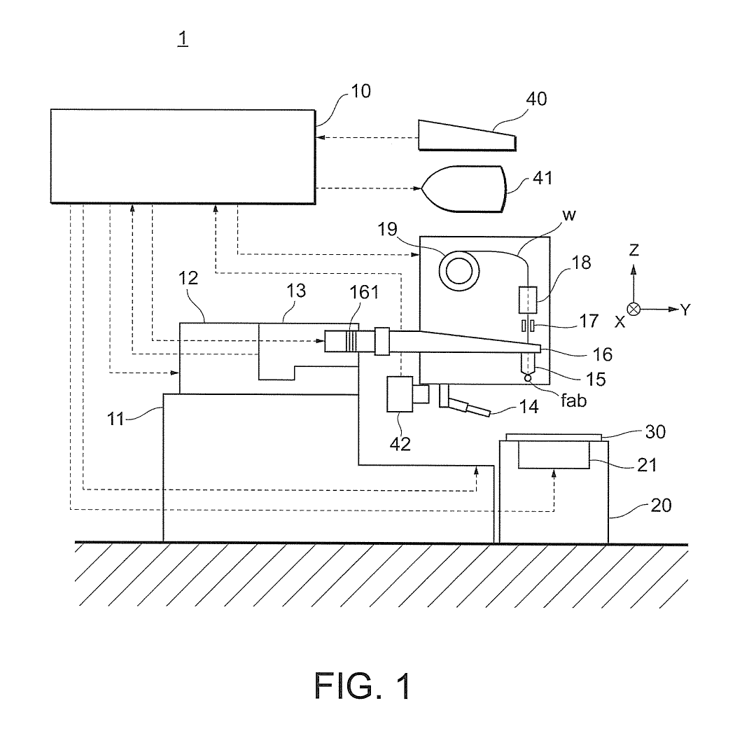

FIG. 1 illustrates a configuration of a bump forming apparatus according to an embodiment. The bump forming apparatus is a bonding apparatus used in the technical field of wire bonding, for example.

As shown in FIG. 1, the bump forming apparatus 1 according to this embodiment is configured to include, for example, a control unit 10, a base 11, an XY table 12, a bonding head 13, a torch electrode 14, a capillary 15, an ultrasonic horn 16, a wire damper 17, a wire tensioner 18, a rotary spool 19, a bonding stage 20, a heater 21, an operation unit 40, a display 41, and a camera 42.

In the following embodiment, a plane parallel to a semiconductor device (e.g. semiconductor die) or a lead frame serving as a bonding target is defined as XY plane and the direction perpendicular to the XY plane is defined as Z direction. The tip position of the capillary 15 is identified with a spatial coordinate (X, Y, Z) represented by an X coordinate, a Y coordinate, and a Z coordinate.

The base 11 has the XY table 12 placed slidably thereon. The XY table 12 is a moving device that is able to move the capillary 15 to a predetermined position on the XY plane based on a drive signal from the control unit 10.

The bonding head 13 is a moving device that is formed integrally with a bonding arm (not shown) and holds the ultrasonic horn 16 movably in the Z direction based on a drive signal from the control unit 10. The bonding head 13 has a lightweight low center-of-gravity structure and can suppress movement of the capillary 15 due to an inertia force generated with the movement of the XY table 12.

The ultrasonic horn 16 is a rod-shaped member including a base end portion, a flange portion, a horn portion, and a leading end portion from the base to the leading end thereof The base end portion is provided with an ultrasonic vibrator 161 arranged to vibrate in response to a drive signal from the control unit 10. The flange portion is attached via the bonding arm to the bonding head 13 in a resonance manner at a position that serves as a node of ultrasonic vibration. The horn portion is an arm extending longer than the diameter of the base end portion, having a structure for amplifying and transmitting the amplitude of vibration by the ultrasonic vibrator 161 to the leading end portion. The end portion is a mounting portion for replaceably holding the capillary 15. The ultrasonic horn 16 has, as a whole, a resonance structure that resonates with vibration by the ultrasonic vibrator 161, in which the ultrasonic vibrator 161 and the flange are positioned at nodes of resonance vibration, while the capillary 15 is positioned at an anti-node of vibration. With these arrangements, the ultrasonic horn 16 serves as a transducer for converting an electrical drive signal into a mechanical vibration.

The capillary 15 is a part of a bonding tool used for bonding. An insertion hole is provided in the capillary 15, through which a wire “w” for bonding is inserted and can be paid out. The capillary 15 is attached replaceably to the ultrasonic horn 16 with a spring force or the like.

The wire damper 17 includes a piezoelectric element arranged to open and close based on a control signal from the control unit 10, whereby the wire “w” can be held and released at predetermined timing.

The wire tensioner 18 can insert the wire “w” therethrough and freely change a tensile force for the wire “w” based on a control signal from the control unit 10 to apply a moderate tensile force to the wire “w” during bonding.

The rotary spool 19 replaceably holds a reel with the wire wound therearound and is arranged to pay out the wire “w” according to the tensile force applied through the wire tensioner 18. It is noted that the material of the wire “w” is selected for good workability and low electrical resistance. For example, gold (Au), silver (Ag), aluminum (Al), or copper (Cu) is commonly used.

The torch electrode 14 is connected to a high-voltage power source not shown through a discharge stabilization resistor not shown and is arranged to generate spark (discharge) based on a control signal from the control unit 10 and, with the heat of the spark, form a free-air ball fab at the leading end of the wire “w” paid out from the tip of the capillary 15. The position of the torch electrode 14 is fixed and, upon discharging, the capillary 15 comes close to the torch electrode 14 until a predetermined distance to generate moderate spark between the leading end of the wire “w” and the torch electrode 14.

The bonding stage 20 is a stage with a working surface to place a work 30 (e.g. substrate or semiconductor die) to be formed with bumps thereon. The heater 21 is provided under the working surface of the bonding stage 20, with which the work 30 can be heated to a temperature suitable for bonding.

The operation unit 40 includes input means such as a trackball, a mouse, a joystick, and a touch panel that serve as an input device for outputting operations by an operator to the control unit 10. The camera 42 is arranged to take an image of the work 30 placed on the working surface of the bonding stage 20. The display 41 is arranged to display an image taken by the camera 42 at a predetermined magnification visible to the operator. The operator operates the operation unit 40 and sets the trajectory of the capillary 15 while observing the work 30 displayed on the display 41.

The control unit 10 is arranged to output various control signals for controlling the bump forming apparatus 1 based on a predetermined software program. Specifically, the control unit 10 performs the following control as a non-limiting example.

(1) Identify the spatial position (X, Y, Z) of the tip of the capillary 15 based on a detection signal from a positional detection sensor not shown and output to the XY table 12 and the bonding head 13 a drive signal for moving the capillary 15 to a spatial position defined by the program.

(2) Output to the ultrasonic vibrator 161 of the ultrasonic horn 16 a control signal for generating ultrasonic vibration during bonding to a bonding point.

(3) Output a control signal for controlling the opening and closing operation of the wire damper 17 such that the wire “w” is paid out as defined by the program. Specifically, set the wire clamper 17 to a releasing state to pay out the wire “w”, while set the wire clamper 17 to a restraining state to form a bent point in the wire “w” or to cut the wire “w”.

(4) Output a control signal for discharging at the torch electrode 14 when forming a free-air ball fab at the leading end of the wire “w”. (5) Output an image from the camera 42 on the display 41. (6) Identify the spatial coordinate of a bonding point, a bent point, etc. based on operations on the operation unit 40.

It is noted that the configuration of the bump forming apparatus 1 is illustrative only and should not be limited thereto. For example, the bonding stage 20 or both the bump forming apparatus 1 and the bonding stage 20 each is provided with a moving device for movement in the X, Y, or Z direction.

Next will be described a bump forming method according to this embodiment.

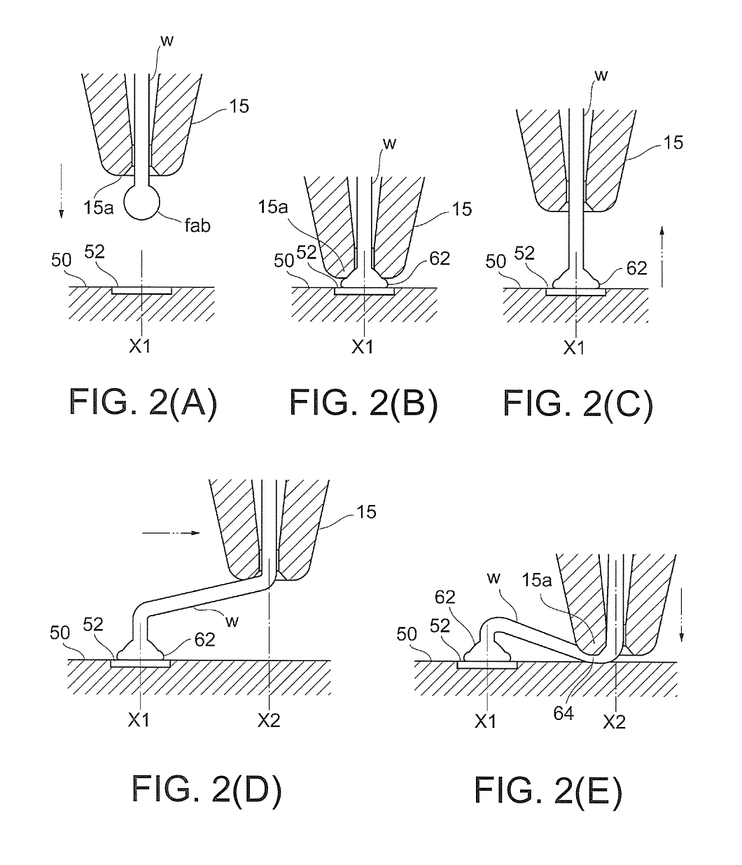

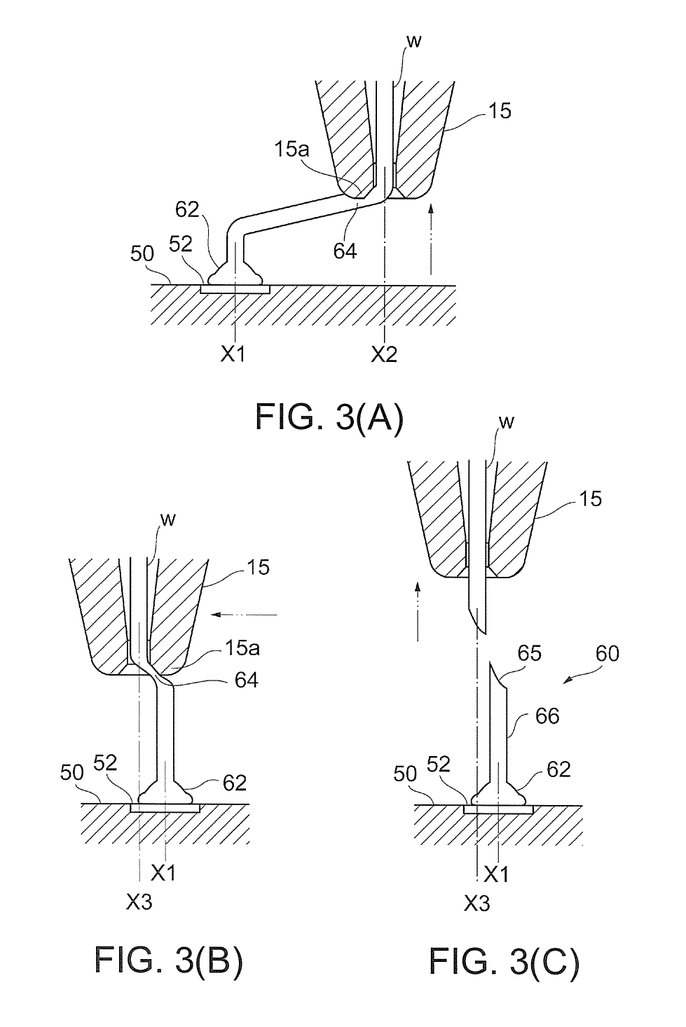

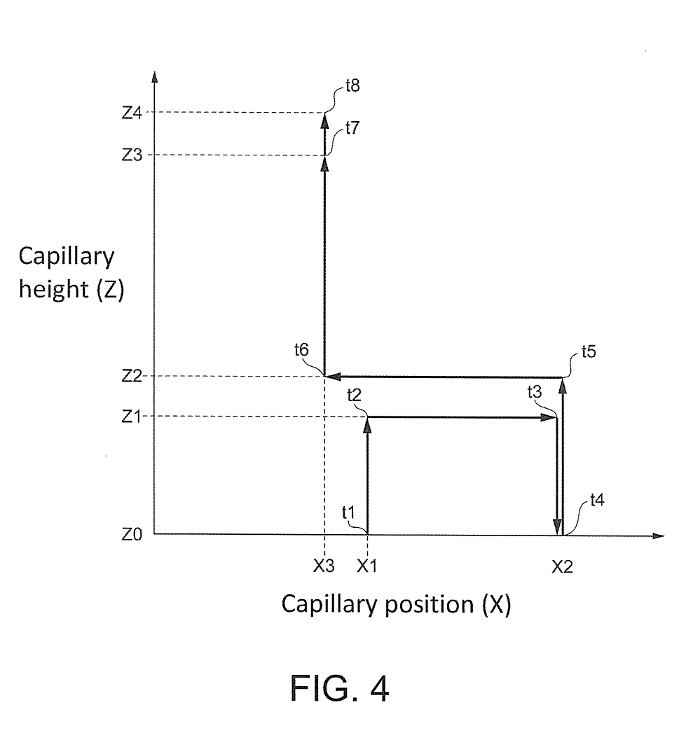

FIGS. 2 (A) to 2 (E) and FIGS. 3 (A) to 3 (C) illustrate the bump forming method according to this embodiment and FIG. 4 is a timing diagram illustrating the bump forming method according to this embodiment. In FIG. 4, the vertical axis represents the height of the capillary (i.e. the Z coordinate of the tip of the capillary), while the horizontal axis represents the position of the capillary (i.e. the X coordinate of the central axis of the capillary). Also, the times t1 to t8 in FIG. 4 denote the time course from the start of performance of the bump forming method according to this embodiment. Further, FIGS. 2 (B) to 2 (E) correspond to the respective times t1 to t4 in FIG. 4, FIGS. 3 (A) and 3 (B) correspond to the respective times t5 and t6 in FIG. 4, and FIG. 3 (C) corresponds to the time t8 in FIG. 4.

First will be described a basic operation of the bump forming apparatus 1.

What should be done first is to set a trajectory of the tip 15a of the capillary 15 (see FIG. 4). Setting a change point (i.e. X, Y, and Z coordinates) at which the direction of movement of the capillary 15 is changed allows the capillary 15 to be moved along a predetermined trajectory.

The operator operates the operation unit 40 while observing images taken by the camera 42 on the display 41 to sequentially set trajectory change points. Specifically, inputting coordinate information through the operation unit 40 and/or positioning and inputting at a desired point a marker displayed on the display 41 causes the X coordinate and the Y coordinate of the point to be set. Numerically inputting the Z-directional displacement of the work 30 from a reference plane (e.g. a surface of the work 30) through the operation unit 40 causes the Z coordinate to be set.

After setting the spatial coordinates of change points for all bumps to be formed, the bonding operation is started. The control unit 10 moves the capillary 15 relatively with respect to the reference plane of the work in the order of the set change points so as to move the capillary 15 along the set trajectory, while repeating release and holding by the wire clamper 17, to perform the bonding operation.

An example of the bump forming method according to this embodiment will hereinafter be described with reference to FIGS. 2 to 4. The following example describes the case where a substrate 50 having an electrode 52 is used as the work and a bump 60 is formed on the electrode 52. It is noted that in the following example, the direction of movement of the capillary 15 is fixed in coordinate in the Y direction.

First, as shown in FIG. 2 (A) (time t0), a free-air ball fab is formed at the leading end of the wire “w”. That is, the torch electrode 14 (see FIG. 1) applied with a predetermined high voltage is brought close to a portion of the wire extending out of the tip 15a of the capillary 15 so as to cause discharge between the portion of the wire and the torch electrode 14. The leading end of the wire is thus melted to be formed with a free-air ball fab due to surface tension. After the formation of the free-air ball fab at the leading end of the wire “w”, the capillary 15 is lowered toward a first point X1 (e.g. the center point of the electrode 52) on the reference plane of the substrate 50. It is noted that in FIG. 4, the trajectory of the capillary at time t0 of FIG. 2 (A) is omitted.

Next, as shown in FIG. 2 (B) (time t1), the free-air ball fab of the wire “w” is bonded to the first point X1 on the reference plane, that is, the electrode 52 on the substrate 50. As the capillary 15 is lowered, at time t1, the free-air ball fab comes into contact with the electrode 52 and, with the load applied on the capillary 15, the free-air ball fab is deformed by the tip 15a of the capillary 15. The tip 15a of the capillary 15 is an opening end portion of the insertion hole of the capillary 15.

During bonding at the first point X1, the control unit 10 supplies a control signal to the ultrasonic horn 16 to cause the ultrasonic vibrator 161 to generate ultrasonic vibration and, through the ultrasonic horn 16 and the capillary 15, apply the ultrasonic vibration to the free-air ball fab. Further, since the electrode 52 on the substrate 50 is applied with a predetermined amount of heat by the heater 21, the mutual effect of the load applied on the free-air ball fab, the ultrasonic vibration, and the heat applied by the heater 21 causes the free-air ball fab to be bonded to the electrode 52. A deformed ball portion 62 of the wire is thus formed.

It is noted that as shown in FIG. 4, the height of the capillary 15 at this time point of bonding (time t1) is Z0, which is substantially equal to the height of the reference plane of the substrate 50 (in a precise sense, the tip 15a of the capillary 15 is positioned slightly higher than the reference plane by the height of a portion of the deformed ball portion 62).

Next, as shown in FIG. 2 (C) (time t2), the capillary 15 is moved in a direction away from the first point while the wire “w” is paid out from the tip of the capillary 15. For example, as indicated by the trajectory of the capillary 15 from time t1 to t2 in FIG. 4, the capillary 15 is raised in the direction perpendicular to the reference plane from Z0 to Z1 at the first point X1. Depending on the moving distance of the capillary 15 from Z0 to Z1, the wire “w” is to be paid out from the tip 15a of the capillary 15 by a predetermined length.

Subsequently, as shown in FIG. 2 (D) (time t3), the capillary 15 is moved in a direction toward a second point X2 on the reference plane while the wire “w” is further paid out from the tip of the capillary 15. Specifically, as indicated by the trajectory of the capillary 15 from time t2 to t3 in FIG. 4, the capillary 15 is moved in the direction parallel to the reference plane at a height Z1 from the first point X1 toward the second point X2. Depending on the moving distance of the capillary 15 from X1 to X2, the wire “w” is to be further paid out from the tip 15a of the capillary 15 by a predetermined length. It is noted that the second point X2 is set outside the electrode 52 on the substrate 50 and/or outside the deformed ball portion 62 of the wire “w” provided on the electrode 52.

As shown in FIG. 2 (E) (time t4), at the second point X2 on the reference plane, the capillary 15 then presses and deformed a portion of the wire “w” on the reference plane of the substrate 50. Specifically, as indicated by the trajectory of the capillary 15 from time t3 to t4 in FIG. 4, the capillary 15 is lowered in the direction perpendicular to the reference plane from Z1 to Z0 at the second point X2. As the capillary 15 is lowered, at time t4, the tip 15a of the capillary 15 comes into contact with a portion of the wire “w” extending from the deformed ball portion 62 to the insertion hole of the capillary 15 and, with the load applied on the capillary 15, the portion of the wire “w” is deformed by the tip 15a of the capillary 15. At the same time, the portion of the wire “w” pressed and deformed by the tip 15a of the capillary 15 is applied with heat by the heater 21.

The pressing force of the capillary 15 against the wire “w” at the second point X2 can be smaller than the pressing force of the capillary 15 against the wire “w” at the first point X1. The pressing force at the second point X2 can also be smaller than the pressing force of the second bonding during common wire bonding. It is noted that during pressing at the second point X2, ultrasound and/or scrubbing operations can also be applied, as needed.

At the second point X2, a thin portion 64 of the wire “w” is thus formed. The thin portion 64 is provided at a position slightly off the central axis of the insertion hole of the capillary 15 toward the first point X1. For example, the thin portion 64 is a tool impression by the tip 15a of the capillary 15. The thin portion 64 of the wire “w” is configured to have a thickness smaller than the diameter of the wire “w”. The thickness of the thin portion 64 can be, for example, roughly 50% of the diameter of the wire “w”. It is noted that at time t4, the wire “w” has not yet been cut at the thin portion 64, but in a state extending integrally from the deformed ball portion 62 into the insertion hole of the capillary 15.

Next, as shown in FIG. 3 (A) (time t5), the capillary 15 is moved along with the thin portion 64 of the wire “w”. For example, as indicated by the trajectory of the capillary 15 from time t4 to t5 in FIG. 4, the capillary 15 is raised in the direction perpendicular to the reference plane from Z0 to Z2 at the second point X2. The height Z2 of the capillary 15 at time t5 can be greater than or substantially equal to the height Z1 of the capillary 15 at times t2 and t3. It is noted that the thin portion 64 of the wire “w” is not necessarily be raised with being in contact with the tip 15a of the capillary 15 as shown in FIG. 3 (A), but can be raised along with the capillary 15 with being separated from the tip 15a of the capillary 15.

As shown in FIG. 3 (B) (time t6), the capillary 15 is then moved from the second point X2 toward a third point X3 and the wire “w” (including the deformed ball portion 62) bonded to the first point X1 is shaped in a manner rising from the reference plane. For example, as indicated by the trajectory of the capillary 15 from time t5 to t6 in FIG. 4, the capillary 15 is moved in the direction parallel to the reference plane at the height Z2 from the second point X2 toward the third point X3. The third point X3 is configured on the line connecting the second point X2 and the first point X1 with the first point X1 being arranged between the third point X3 and the second point X2. As shown in FIG. 3 (B), the third point X3 is set such that the side of the tip 15a of the capillary 15 closer to the second point X2 (the right side portion on paper in FIG. 3 (B)) is positioned approximately over the first point X1. In other words, the third point X3 is set such that the central axis of the insertion hole of the capillary 15 is positioned opposite to the second point X2 with respect to the first point X1. That is, the preformed shape of the wire “w” is corrected such that the wire “w” bonded to the first point X1 rises perpendicularly from the reference plane by moving the capillary 15 such that the central axis of the capillary 15 gets over the central axis (corresponding to X1) of the wire “w” bonded to the first point X1.

Next, as indicated by the trajectory from time t6 to t7 in FIG. 4, the capillary 15 is raised to a height Z3 in the direction perpendicular to the reference plane. Upon this, the wire clamper 17 (see FIG. 1) is set to a state of releasing the wire “w” so that a predetermined amount of wire “w” is paid out from the tip of the capillary 15 depending on the moving distance of the capillary 15. That is, the amount of pay-out from time t6 to t7 corresponds to the wire tail for the next bump formation. Thereafter, with the wire “w” restrained by the wire clamper 17, as indicated by the trajectory from time t7 to t8 in FIG. 4, the capillary 15 is further raised to a height Z4 in the direction perpendicular to the reference plane. The wire “w” is thus forcibly applied with a tensile stress to be cut at the thin portion 64, as shown in FIG. 3 (C). It is noted that the wire damper 17 is in a state of restraining the wire “w” during the period from time t7 to t8, following the period from time t1 to t6 at least during which the wire “w” is released.

A bump 60 having a shape (predetermined height) rising from the reference plane can thus be formed on the electrode 52 of the substrate 50. In the case of forming multiple bumps on the substrate 50, the above described steps are repeated for each electrode.

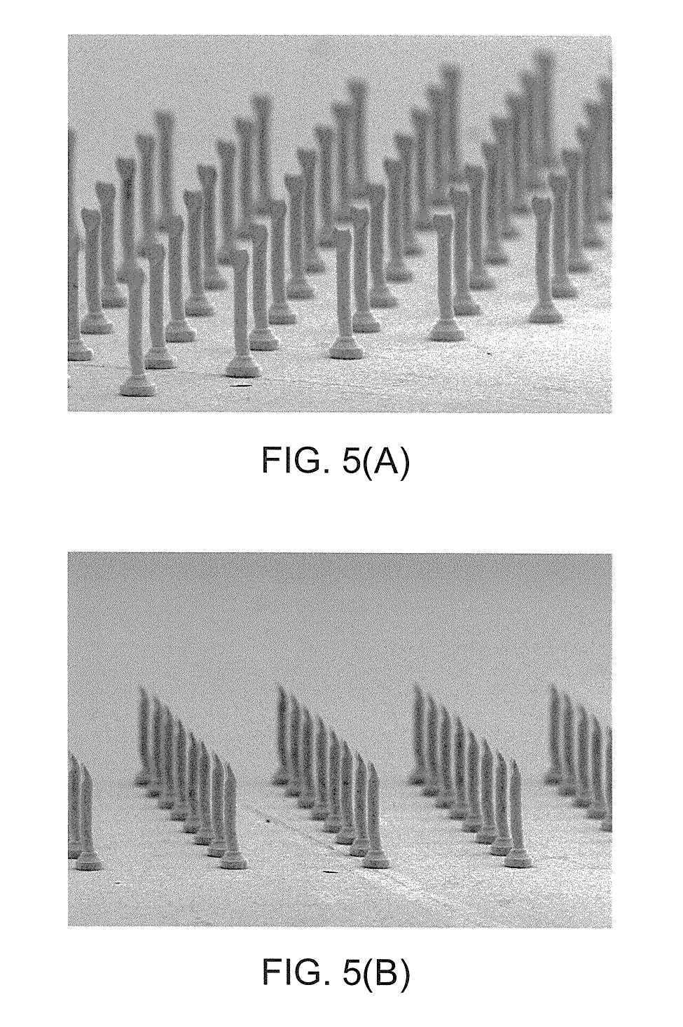

As shown in FIG. 3 (C), the bump 60 formed by the bump forming method according to this embodiment includes the deformed ball portion 62 bonded to the reference plane and a neck portion 66 formed in a manner rising from the reference plane on the deformed ball portion 62. The height of the neck portion 66 is approximately equal to the difference between the height Z1 and the height Z0 shown in FIG. 4. The neck portion 66 has a leading end portion 65 formed by the above described thin portion 64 cut with the movement of the capillary 15. As shown in FIG. 5 (A), the leading end portion 65 of the neck portion 66 has. a shape in which the neck portion 66 has an increased width toward the leading end. As shown in FIG. 5 (B), the leading end portion 65 of the neck portion 66 also has an inclined surface formed by being pressed and deformed by the capillary 15, having a shape tapered toward the leading end.

As described heretofore, in accordance with the bump forming method according to this embodiment, the wire “w” is formed with the thin portion 64 using the bonding tool (capillary 15) and the wire bonded to the first point X1 is shaped in a manner rising from the reference plane, and then the wire “w” is cut at the thin portion 64, so that a bump is formed having a shape rising from the reference plane at the first point X1. It is therefore possible to form a bump 60 having a desired height more easily and efficiently.

The above described bump forming method is used to manufacture a semiconductor device. The semiconductor device includes a bump 60 formed through the above described steps. The bump 60 is particularly suitable for applications that require getting above a certain height at a pitch distance narrowed to some extent.

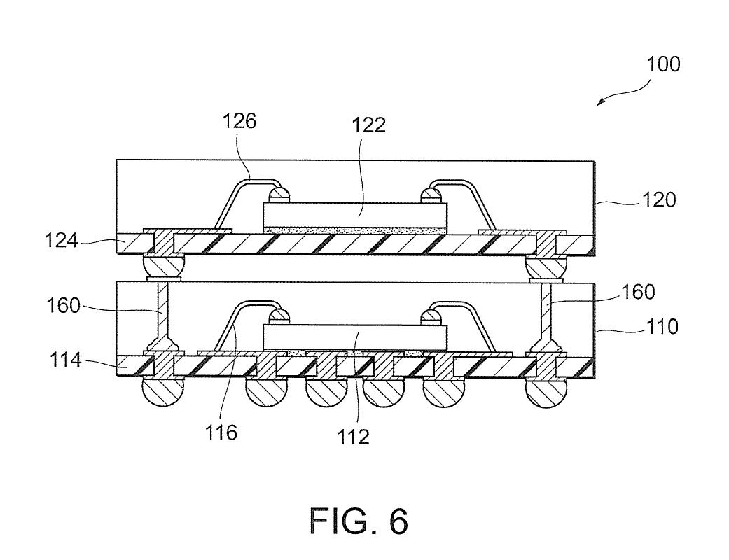

As shown in FIG. 6, a bump 160 according to this embodiment is also applied to a semiconductor device 100 having a packaging configuration of POP (Package On Package). The semiconductor device 100 includes a first package 110 configured such that a semiconductor die 112 and a substrate 114 are connected electrically through a wire 116 and a second package 120 configured such that a semiconductor die 122 and a substrate 124 are connected electrically through a wire 126, with the second package 120 stacked on the first package 110. In the first package 110, the bump 160 is formed on the substrate 114 and configured to be higher than the semiconductor die 112 and the wire 116 that are mounted on the substrate 114. This allows an electrical connection to the exterior to be provided on the upper surface of the package 110 while keeping a predetermined pitch distance. It is noted that semiconductor device bumps formed by the bump forming method according to this embodiment are applicable not only to the above described semiconductor device example, but also to various other aspects.

The present invention is not limited to the above described embodiment, but is applied in various variations.

The trajectory of movement of the bonding tool (capillary 15) is not limited to the aspect indicated by the arrows in FIG. 4, but is employed various other aspects.

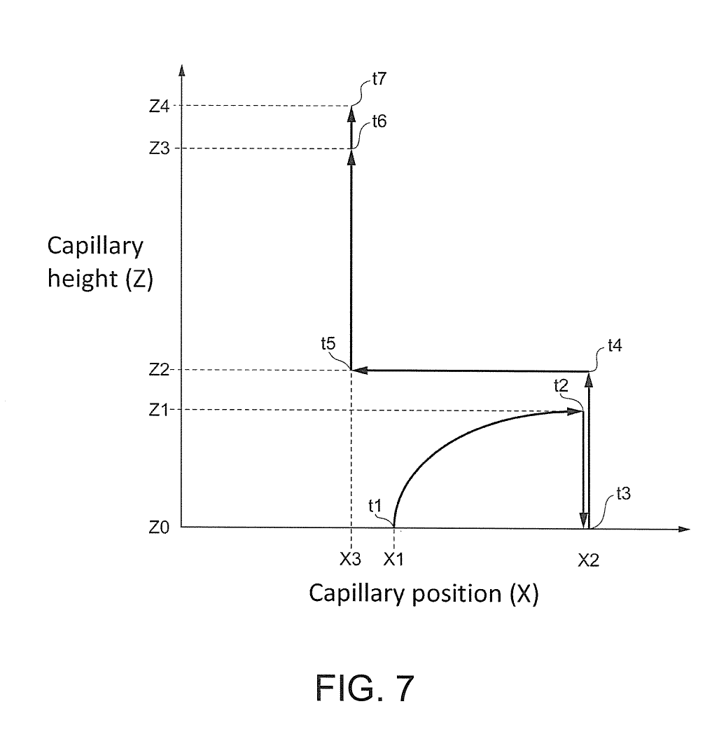

Herein, FIGS. 7 to 10 illustrate variations of the trajectory of movement of the capillary 15. It is noted that the spatial coordinates of the capillary 15 and the processing details associated therewith are the same as those in the description of the above embodiment. In the following variations, the trajectory of movement of the capillary 15 after wire bonding at the first point X1 to wire rise-up and shaping at the first point X1 is different from that of the example shown in FIG. 4.

For example, as shown in FIG. 7, from time t1 to t2, the capillary 15 is moved toward above the second point X2 to the height Z1 in a predetermined curve (e.g. a curve concave toward the reference plane as illustrated). That is, the capillary 15 is moved in a semicircular trajectory. This allows the capillary 15 to be arranged over the second point X2 without passing through the coordinate of the height Z1 at the first point X1 and thereby the moving distance of the capillary to be reduced, whereby it is possible to form a bump more efficiently. It is also possible to move the capillary 15 with no deformation in the shape of the wire bonded to the first point X1. It is noted that the trajectory of movement of the capillary 15 from time t2 to t7 in FIG. 7 is as described for time t3 to t8 in FIG. 4.

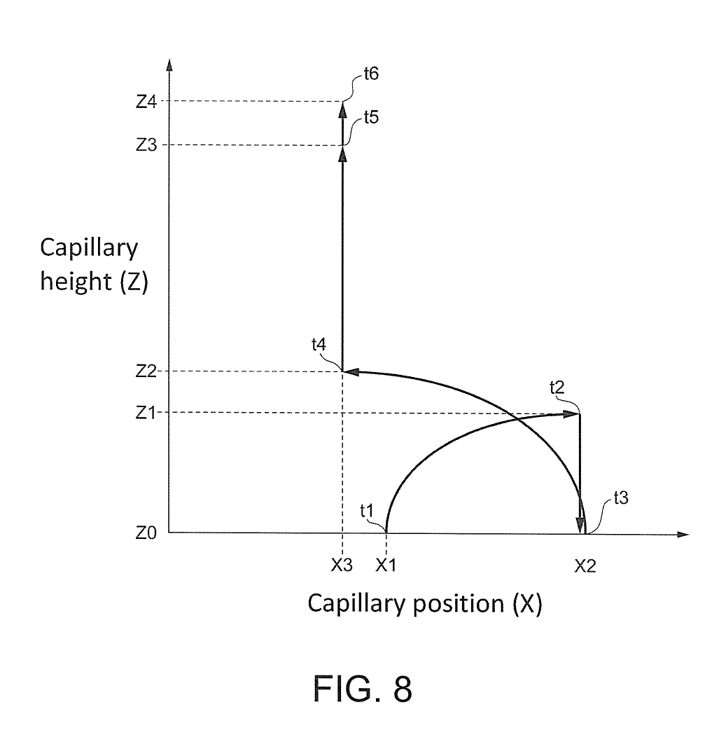

Alternatively, as shown in FIG. 8, after moved from time t1 to t3 as is the case with the example in FIG. 7, the capillary 15 is moved, from time t3 to t4, toward above the third point X3 to the height Z2 in a predetermined curve (e.g. a curve concave toward the reference plane as illustrated). This allows the capillary 15 to be arranged over the third point X3 without passing through the coordinate of the height Z2 at the second point X2 and thereby the moving distance of the capillary to be reduced, whereby it is possible to form a bump more efficiently. It is also possible to move the capillary 15 with no deformation in the shape of the wire bonded to the second point X2. It is noted that the trajectory of movement of the capillary 15 from time t4 to t6 in FIG. 8 is as described for time t6 to t8 in FIG. 4.

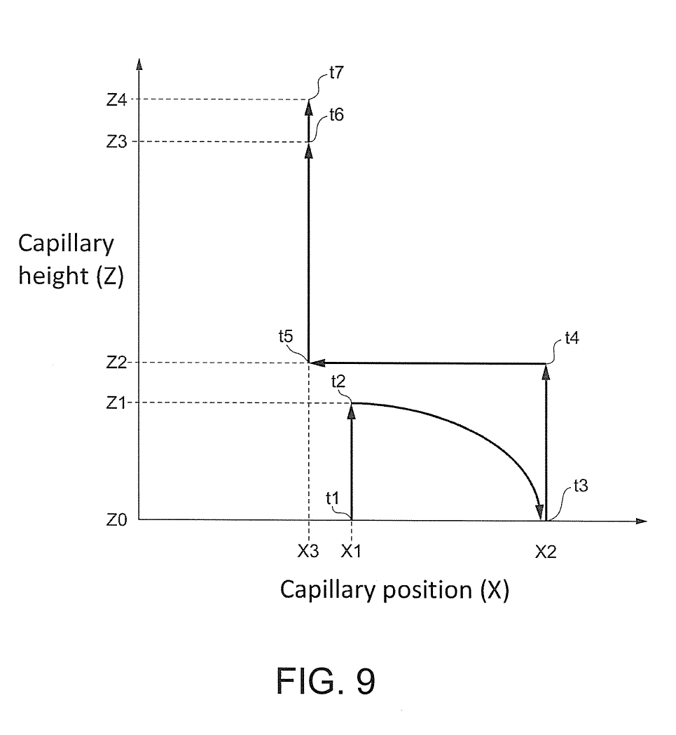

Alternatively, as shown in FIG. 9, after moved from time t1 to t2 as is the case with the example in FIG. 4, the capillary 15 is moved, from time t2 to t3, toward the second point X2 in a predetermined curve (e.g. a curve concave toward the reference plane as illustrated). This allows the capillary 15 to be arranged at the second point X2 without passing through the coordinate of the height Z1 at the second point X2 and thereby the moving distance of the capillary to be reduced, whereby it is possible to form a bump more efficiently. It is also possible to move the capillary 15 with no deformation in the shape of the wire bonded to the first point X1. It is noted that the trajectory of movement of the capillary 15 from time t3 to t7 in FIG. 9 is as described for time t4 to t8 in FIG. 4.

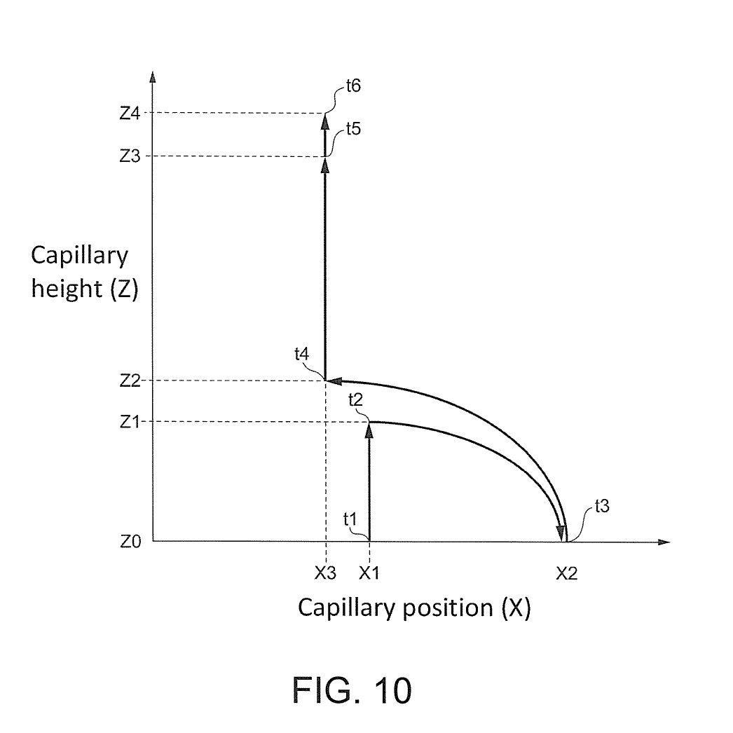

Alternatively, as shown in FIG. 10, after moved from time t1 to t3 as is the case with the example in FIG. 9, the capillary 15 is moved from time t3 to t4 as is the case with the example in FIG. 8. It is noted that the trajectory of movement of the capillary 15 from time t4 to t6 in FIG. 10 is as described for time t6 to t8 in FIG. 4.

Although the above embodiment has described the case where a ball fab is first formed at the leading end of the wire “w” as shown in FIG. 2 (A), the ball forming step is omitted. For example, if the material of the wire is aluminum, a portion of the wire is bonded to the first point X1 without forming a ball.

Although the above embodiment has described the case where the capillary 15 is moved to the third point X3, which is positioned opposite to the second point X2 with respect to the first point X1, such that the wire “w” is shaped, the aspect of movement of the capillary is not limited thereto as long as the wire “w” can be shaped in a rise-up manner at the first point X1. For example, the capillary 15 is moved from the second point X2 to the first point X1 with its Y coordinate being fixed. In this case, the Y coordinate is changed also. In the bump forming method according to this embodiment, the aspect of movement of the capillary 15 to form a bump having a rise-up shape at the first point X1 can vary in different ways depending on the material of the wire, the pressing force on the wire, the load applied on the wire according to the trajectory of the capillary 15, etc.

The examples and applications described through the above described embodiment of the invention can be combined appropriately depending on the intended use or can be changed or modified for use, and the present invention is not limited to the description of the above embodiment. It is obvious from the description of the appended claims that such combined, changed, or modified modes could also be included within the technical scope of the present invention.

1. A bump forming method of semiconductor devices using a bonding tool with a wire inserted therethrough, the method comprising:
a bonding step of lowering the bonding tool toward a first point on a reference plane and bonding the leading end of the wire extending out of the tip of the bonding tool to the first point;
a wire pay-out step of moving the bonding tool in a direction away from the first point while paying out the wire from the tip of the bonding tool;
a thin portion forming step of pressing a portion of the wire at a second point on the reference plane using the bonding tool to form a thin portion in the wire;
a wire shaping step of moving the bonding tool along with the thin portion of the wire and shaping the wire bonded to the first point in a manner rising from the reference plane; and
a bump forming step of cutting the wire at the thin portion to form a bump having a shape rising from the reference plane at the first point.

2. The bump forming method according to claim 1, wherein in the wire pay-out step, the bonding tool is moved to a predetermined height in a direction perpendicular to the reference plane, moved toward the second point in the parallel direction while being kept at the predetermined height, and moved toward the second point in the direction perpendicular to the reference plane.

3. The bump forming method according to claim 1, wherein in the wire pay-out step, the bonding tool is moved to a predetermined height in a direction perpendicular to the reference plane and moved toward the second point in a predetermined curve.

4. The bump forming method according to claim 1, wherein in the wire pay-out step, the bonding tool is moved toward above the second point to a predetermined height in a predetermined curve and moved toward the second point in a direction perpendicular to the reference plane.

5. The bump forming method according to claim 1, wherein in the wire shaping step, the bonding tool is moved toward above a third point on the reference plane, the third point configured on the line connecting the second point and the first point with the first point being arranged between the third point and the second point.

6. The bump forming method according to claim 5, wherein in the wire shaping step, the bonding tool is moved to a predetermined height in a direction perpendicular to the reference plane and moved toward the third point in the parallel direction while being kept at the predetermined height.

7. The bump forming method according to claim 5, wherein in the wire shaping step, the bonding tool is moved toward above the third point to a predetermined height in a predetermined curve.

8. The bump forming method according to claim 1, further comprising, after the wire shaping step and before the wire cutting step, a step of raising the bonding tool while paying out the wire from the tip of the bonding tool.

9. The bump forming method according to claim 8, wherein in the bump forming step, the bonding tool is raised further, with the wire being restrained by a wire clamper, to cut the wire at the thin portion.

10. The bump forming method according to claim 1, further comprising, before the bonding step, a step of forming the leading end of the wire into a ball.

11. The bump forming method according to claim 1, wherein in the thin portion forming step, the wire is pressed such that the thin portion of the wire has a thickness approximately half the diameter of the wire.

12. A semiconductor device manufacturing method comprising the bump forming method according to claim 1.

13. A bump forming apparatus for forming a bump of semiconductor devices using a bonding tool with a wire inserted therethrough, the apparatus comprising a control unit for controlling the operation of the bonding tool, wherein the control unit is configured to perform:
a bonding step of lowering the bonding tool toward a first point on a reference plane and bonding the leading end of the wire extending out of the tip of the bonding tool to the first point;
a wire pay-out step of moving the bonding tool in a direction away from the first point while paying out the wire from the tip of the bonding tool;
a thin portion forming step of pressing a portion of the wire at a second point on the reference plane using the bonding tool to form a thin portion in the wire;
a wire shaping step of moving the bonding tool along with the thin portion of the wire and shaping the wire bonded to the first point in a manner rising from the reference plane; and
a bump forming step of cutting the wire at the thin portion to form a bump having a shape rising from the reference plane at the first point.
